(19) United States
(12) Patent Application Publication
(10) Pub. No.: US 2025/0364433 A1
(43) Pub. Date: Nov. 27, 2025

(54) Semiconductor Device and Method of Making Using Shape-Memory Alloy Structures

(71) Applicant: STATS ChipPAC Pte. Ltd., Singapore (SG)

(72) Inventors: SeokBeom Heo, Incheon (KR); Seongkuk Kim, Gyeonggi-do (KR); Soyeong Park, Incheon (KR); JaeHyuk Choi, Incheon (KR); TaeYoung Lee, Incheon (KR)

(73) Assignee: STATS ChipPAC Pte. Ltd., Singapore (SG)

(21) Appl. No.: 18/670,342

(22) Filed: May 21, 2024

(51) Int. Cl. H01L 23/00; F03G 7/06; H01L 21/48; H01L 23/538

(52) U.S. Cl. CPC H01L 23/562; F03G 7/0614; H01L 21/4853; H01L 21/4857; H01L 23/5383; H01L 23/5385

(57) ABSTRACT

A semiconductor device has an interposer. A shape-metal alloy (SMA) structure is disposed over the interposer. The SMA structure is formed of Nickel-Titanium. A solder bump and electrical component are disposed over the interposer. The interposer is disposed over a substrate with the SMA structure, solder bump, and electrical component between the interposer and substrate. The solder bump is reflowed.

### FIELD OF THE INVENTION

The present invention relates in general to semiconductor devices and, more particularly, to a semiconductor device and method of making using shape-memory alloy (SMA) structures.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Semiconductor device manufacturers are continually striving to make smaller and more advanced semiconductor packages to meet the demands of electronic device manufacturers and consumers alike. Substrate and interposer warpage is a big problem for advanced semiconductor packaging. Smaller devices with thinner substrates and interposers are subject to more warpage during manufacturing. Therefore, a need exists for advanced packages manufactured with shape-memory alloy (SMA) structures.

### BRIEF DESCRIPTION OF THE DRAWINGS

FIGS. 1a-1c illustrate a semiconductor wafer with a plurality of semiconductor die separated by a saw street;

FIGS. 2a-2p illustrate a process of forming a semiconductor package with shape-memory alloy (SMA) structures; and

FIGS. 3a and 3b illustrate integrating the semiconductor packages into an electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the semiconductor package. The electrical connections can be made with conductive layers, bumps, stud bumps, conductive paste, or wirebonds. An encapsulant or other molding material is deposited over the semiconductor package to provide physical support and electrical isolation. The finished semiconductor package is then inserted into an electrical system and the functionality of the semiconductor device is made available to the other system components.

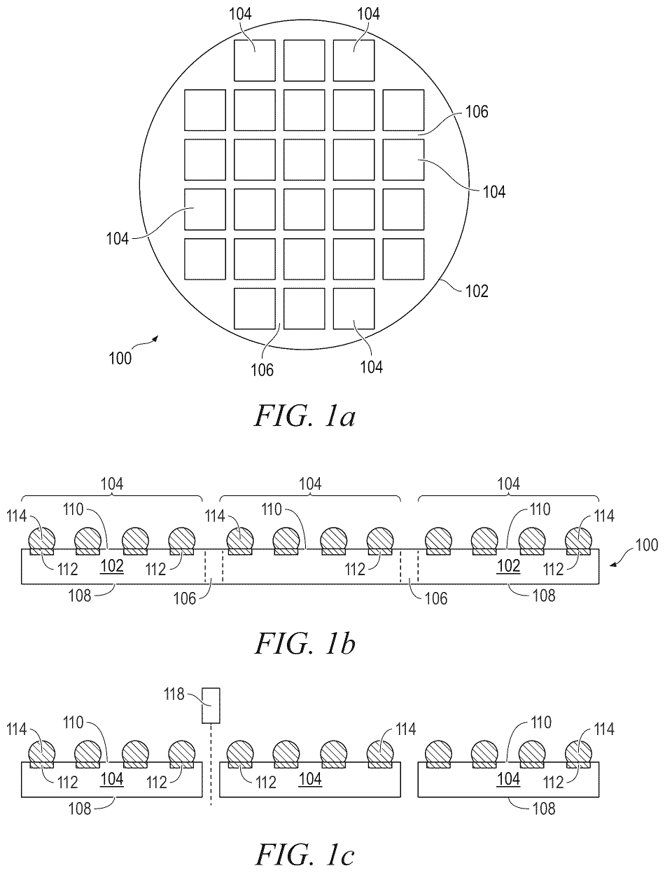

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

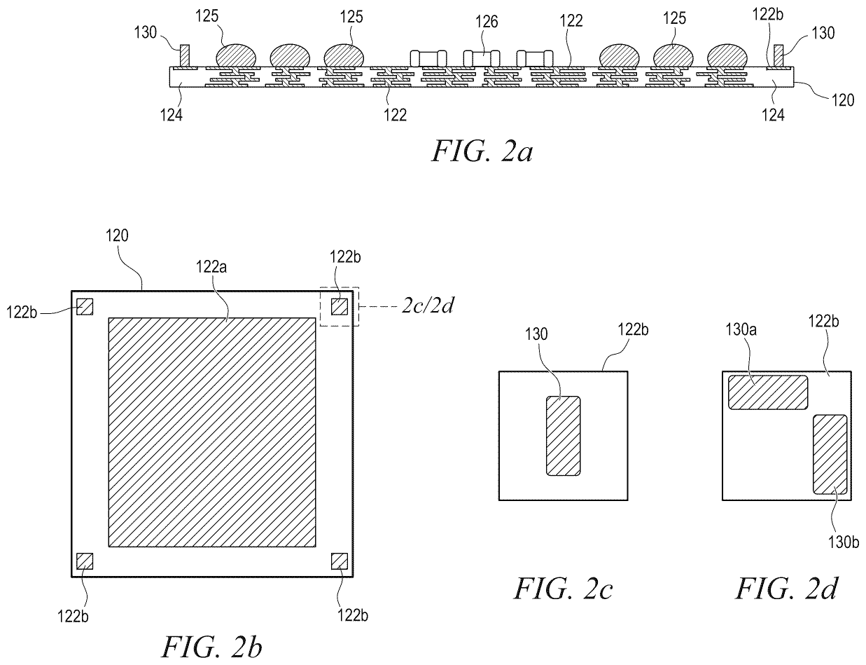

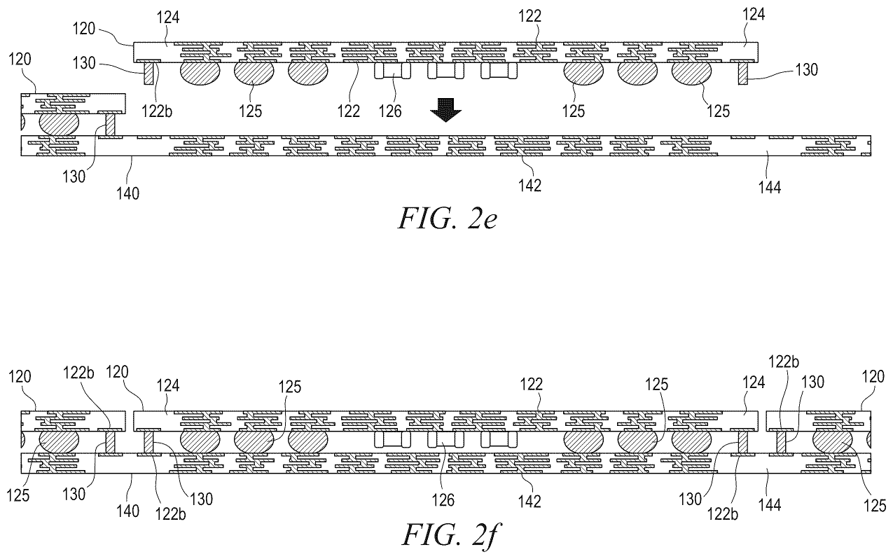

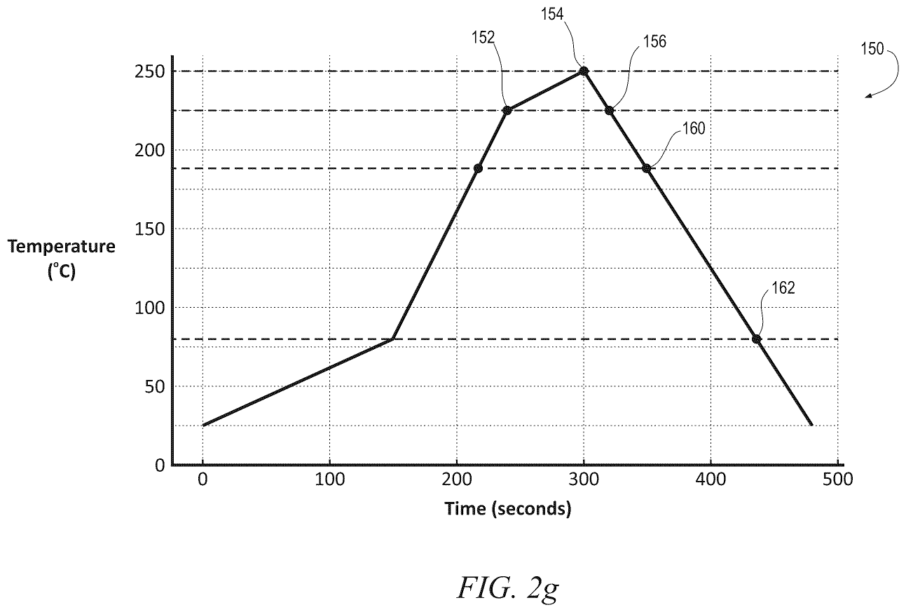

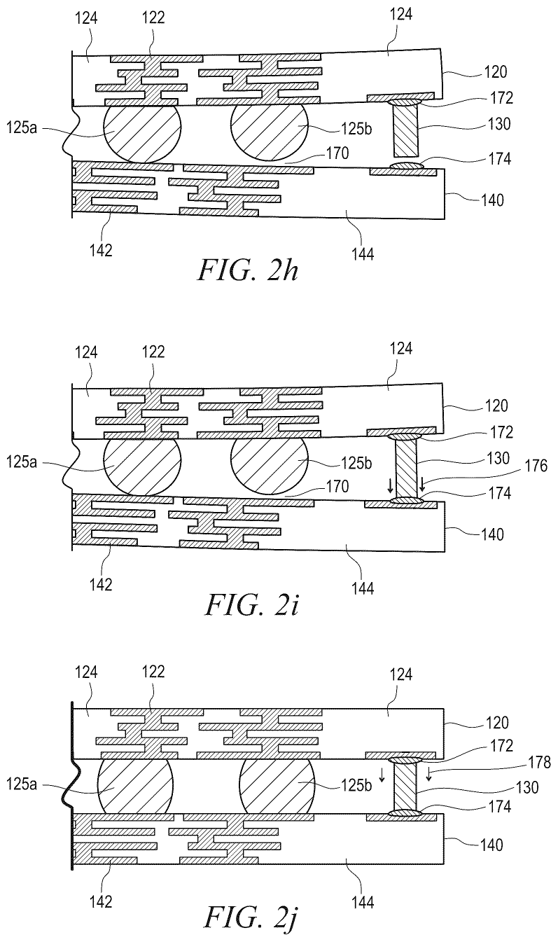

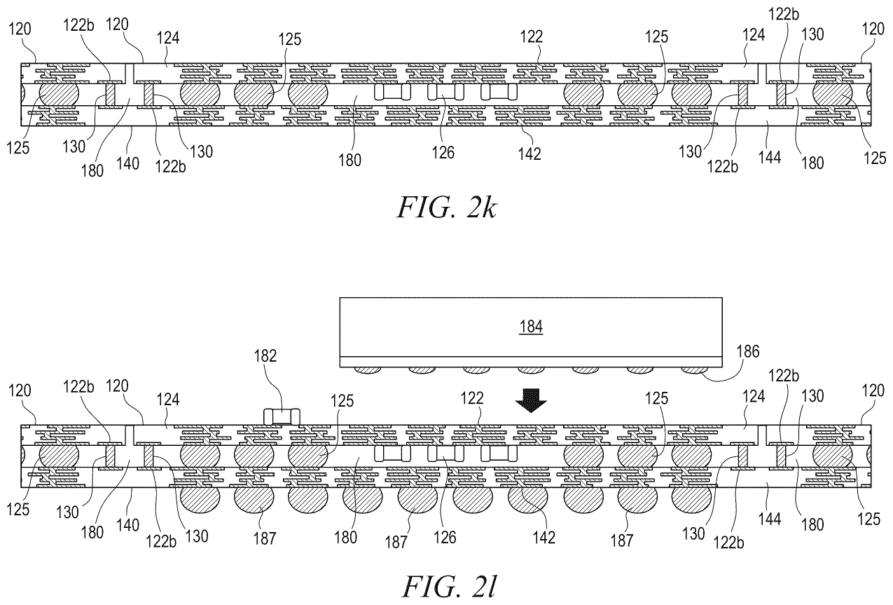

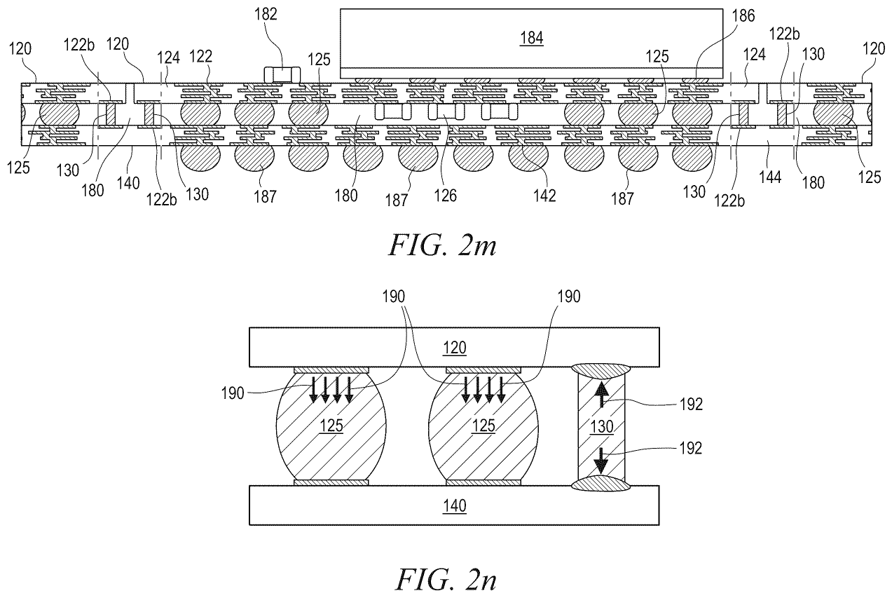

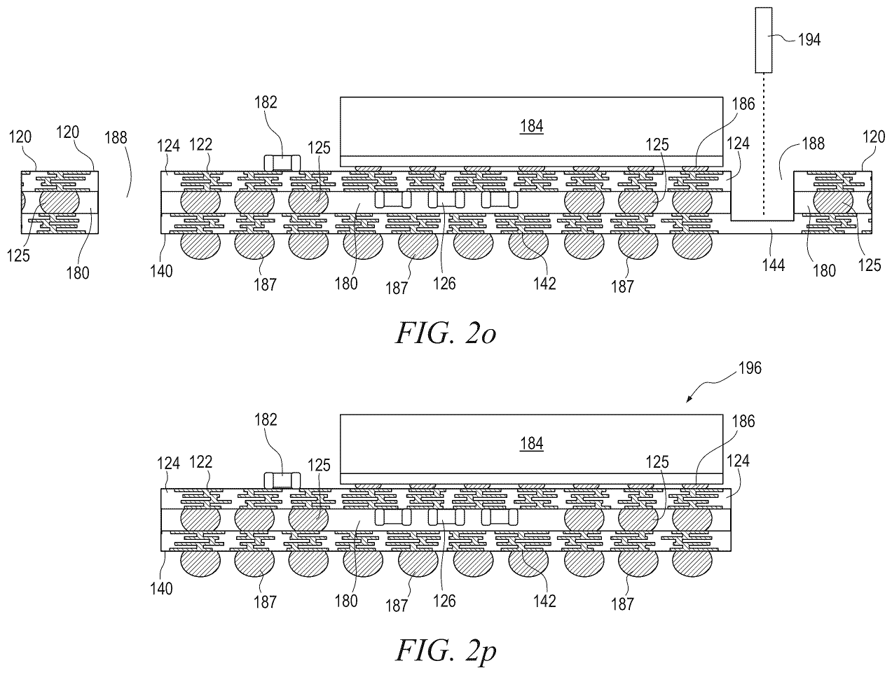

FIGS. 2a-2p illustrate a process of forming semiconductor packages with shape-memory alloy (SMA) structures. FIG. 2a shows a cross-sectional view of multi-layered interconnect substrate or interposer 120 including conductive layers 122 and insulating layers 124. While only a single interposer 120 is shown, hundreds or thousands of interposers are commonly manufactured together in a single sheet or panel before being singulated from each other.

Conductive layer 122 can be one or more layers of Al, Cu, Sn, Ni, Au, Ag, or other suitable electrically conductive material. Conductive layers can be formed using PVD, CVD, electrolytic plating, electroless plating, or other suitable metal deposition process. Conductive layer 122 provides horizontal electrical interconnect across substrate 120 and vertical electrical interconnect between the top and bottom surfaces. Portions of conductive layer 122 can be electrically common or electrically isolated depending on the design and function of semiconductor die 104 and other electrical components.

Insulating layers 124 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Insulating layers 124 provide isolation between and structural support for conductive layers 122. Any other suitable type of substrate or interposer is used for interposer 120 in other embodiments.

Solder bumps 125 are formed on contact pads of conductive layers 122 as described above for bumps 114, e.g., using a stencil printing or ball drop process. Discrete passive components 126, e.g., resistors, inductors, or capacitors, are picked and placed or otherwise mounted on interposer 120. Components 126 are electrically and physically coupled to interposer 120 using solder or solder paste. Any desired electrical components, including semiconductor die 104, other semiconductor die, semiconductor packages, and discrete active components can be mounted on interposer 120 as desired to implement the intended electrical functionality of the semiconductor packages being formed.

SMA pillars 130 are disposed near the edges, corners, or ends of each interposer 120 unit. Interposer 120 is a square or rectangle in some embodiments, and four SMA pillars 130 are disposed with one in each corner of the interposer. An SMA is an alloy that can be deformed when cold but returns to its pre-deformed (“remembered”) shape when heated. SMA pillars 130 are formed of Nickel-Titanium (NiTi), also known as Nitinol, in one embodiment. The transformation temperatures of Nitinol can be adjusted during the manufacturing process to suit specific applications, including those involving reflow soldering temperatures typically ranging from 183 to 260° C. Other SMA materials are used in other embodiments, e.g., copper-aluminum-nickel, Fe—Mn—Si, Cu—Zn—Al and Cu—Al—Ni, and other alloys of zinc, copper, gold, or iron.

SMA pillars 130 are formed by depositing the desired material into mask openings on interposer 120. Alternatively, another substrate is used to form SMA pillar 130 in mask openings and then the SMA pillars are picked and placed onto interposer 120. SMA pillars 130 are cut from a sheet of material in another embodiment.

SMA pillars 130 are commonly attached to contact pads of conductive layer 122 using a solder or solder paste. SMA pillars 130 can be dipped in solder paste before being disposed onto interposer 120. In one embodiment, the contact pads of conductive layer 122 that SMA pillars 130 are mounted onto are electrically isolated from all portions of conductive layers 122 that are electrically operative in the final package being formed, i.e., SMA pillars 130 have no internal electrical interconnect to the package being formed. SMA pillars 130 are also optionally formed in saw streets of the package being formed so that the pillars are cut out and removed when the final packages are singulated.

FIGS. 2b-2d illustrate plan views of interposer 120 in one exemplary embodiment. Conductive layer 122 forms a redistribution layer (RDL) pattern 122a in the middle of the interposer footprint and isolated contact pads 122b in the corners. RDL pattern 122a is drawn as a square just to illustrate the general area occupied by the RDL pattern. In practice, RDL pattern 122a would consist of contact pads, conductive traces, and similar structures rather than only one large conductive plane. Contact pads 122b are formed for the mounting of SMA pillars 130. In one embodiment, contact pads 122b are formed completely non-overlapping with RDL pattern 122a in both the length and width dimension of interposer 120. That allows contact pads 122b to be completely removed by singulating in only two perpendicular directions without removing any portion of RDL pattern 122a.

FIG. 2c shows SMA pillar 130 disposed on contact pad 122b. SMA pillar 130 is rectangular with approximately a 2:1 aspect ratio. Each SMA pillar 130 in all four corners can be oriented in parallel to each other. Alternatively, the pillars can be sloped in to face the center of interposer 120 or disposed in any other suitable orientation. In other embodiments, SMA pillars 130 are square, circular, or other suitable shapes. FIG. 2d shows another embodiment where each corner contact pad 122b has two SMA pillars 130a and 130b disposed thereon. Each SMA pillar 130a and 130b is disposed adjacent to an edge of interposer 120 and oriented in parallel to the adjacent edge of the interposer. Therefore, each edge of interposer 120 has two SMA pillars oriented in parallel to that edge, one at each end. In other embodiments, additional contact pads 122b and SMA pillars 130 can be formed and disposed along edges between corners in any suitable number and distribution.

In FIG. 2e, a plurality of interposers 120 is disposed over a package substrate 140 with bumps 125, components 126, and SMA pillars 130 oriented toward the substrate, i.e., between substrate 140 and interposer 120. Substrate 140 is structured similarly to interposer 120 with conductive layers 142 formed and operating similar to conductive layers 122 and insulating layers 144 being formed and operating similar to insulating layers 124. Optionally, components 126 and any other desired electrical components, such as those mentioned as possibly being mounted on interposer 120, are mounted on substrate 140 in addition to or instead of on the interposer. SMA pillars 130 are mounted onto substrate 140 instead of interposer 120 in some embodiments.

Interposers 120 are disposed with bumps 125 and SMA pillars 130 aligned to contact pads of conductive layer 142. SMA pillars 130 have solder paste disposed on their ends opposite interposer 120 for attachment of the pillars to substrate 140. Alternatively, contact pads of conductive layer 142 have solder paste printed thereon for attachment of SMA pillars 130. The contact pads of conductive layer 142 are isolated and non-overlapping with the conductive layer's RDL pattern as shown in FIG. 2b for conductive layer 122. FIG. 2f shows interposer 120 resting on substrate 140 ready for reflow of said solder paste to attach pillars 130, as well as reflow of bumps 125 to electrically connect RDL patterns of conductive layers 122 and 142.

FIG. 2g shows a typical temperature profile 150 for solder reflow of SAC305 solder. The oven temperature begins increasing at a time of zero seconds and reaches 250 degrees Celsius at 300 seconds. At 300 seconds, the oven is turned off and the temperature begins to fall until reaching its original temperature of approximately 25 degrees Celsius at around time 480 seconds.

At point 152, after approximately 235 seconds, the Austenite start temperature is reached for SMA pillars 130. The Austenite finish temperature is reached at point 154, after approximately 300 seconds, before allowing the temperature to fall. The temperature remains within the Austenite zone until falling back under the Austenite start temperature at point 156. The area between points 152 and 156 is known as the dwell zone because the temperature dwells within the Austenite zone.

Austenite is the high-temperature phase of SMAs and typically has a cubic crystal structure with higher symmetry. The Austenite phase of SMA structures increases the structural height of SMA pillars 130. The increased height of SMA pillars 130 during solder reflow has several benefits described below.

At point 160, approximately 350 seconds into the process, temperature profile 150 cools to the Martensite start temperature. The temperature profile remains within the Martensite zone until point 162, at approximately 425 seconds, when the temperature reaches the Martensite finish temperature. The area between points 160 and 162 is referred to as the cooling or Martensite zone. Martensite is the low-temperature phase and generally features a lower symmetry. Within the Martensite zone, SMA pillars 130 shrink or return to their original shape from before the Austenite zone. The beginning and ending temperatures for the Austenite zone and Martensite zone can be configured by modifying the ratio of Ni to Ti or other components or controlling the amount of oxygen or carbon that combines with Titanium atoms.

FIGS. 2h-2j illustrate one benefit of SMA pillars 130 to correcting warpage. In FIG. 2h, interposer 120 has been set on substrate 140, but solder bumps 125 have not been reflowed yet. Interposer 120 has its edges or ends warped upward, so that the inner bumps 125a rest on substrate 140 but the outer bumps 125b have a gap 170 between the bumps and substrate 140. Gap 170 can result in an undesired electrical discontinuity after reflow if bump 125b does not properly wet onto conductive layer 142 due to the separation. SMA pillar 130 is attached to interposer 120 with solder paste 172 but fails to make physical contact with solder paste 174 on substrate 140.

FIG. 2i shows substrate 140 and interposer 120 in the Austenite zone. SMA pillar 130 has grown as indicated by arrows 176. The Austenite growth of SMA pillar 130 increases the pillar's height so that the pillar physically contacts solder paste 174 on substrate 140. Solder paste 174 reflows and wets onto SMA pillar 130.

FIG. 2j shows SMA pillar 130 shrinking again in the Martensite phase. Arrows 178 illustrate the shrinking of SMA pillar 130 pulling down on interposer 120. The force applied by SMA pillar 130 shrinking corrects warpage of interposer 120, resulting in a substantially flat interposer. Gap 170 is closed so that solder bump 125b reflows properly onto a contact pad of conductive layer 142. SMA pillars 130 pull the corners, edges, or ends of interposer 120 down toward substrate 140.

In FIG. 2k, encapsulant or molding compound 180 is deposited over and between substrate 140 and interposers 120, including around SMA pillars 130, bumps 125, and components 126, using a paste printing, compressive molding, transfer molding, liquid encapsulant molding, vacuum lamination, spin coating, or other suitable applicator. Encapsulant 180 can be liquid or granular polymer composite material, such as epoxy resin, epoxy acrylate, or another suitable polymer, with or without a suitable filler. Encapsulant 180 is non-conductive, provides structural support, and environmentally protects the semiconductor device from external elements and contaminants.

In some embodiments, SMA pillars 130 again grow during the molding process, which may be performed at an elevated temperature. The growth of SMA pillars 130 provides added support for interposer 120 over substrate 140 to reduce the collapse of solder bumps 125.

In FIG. 2l, additional electrical components are mounted onto interposer 120 opposite components 126. For example, a discrete component 182 and semiconductor package 184 are mounted onto interposer 120. Semiconductor package 184 includes semiconductor die 104 in one embodiment. Semiconductor package 184 can be a system-in-package module or chiplet in some embodiments, with a plurality of components packaged together.

Semiconductor package 184 includes solder bumps 186 on the bottom surface of the package, which will be reflowed onto contact pads of conductive layer 122 to electrically and physically contact the semiconductor package to interposer 120. FIG. 2m shows packages 184 stacked on interposers 120 and ready for reflow. Bumps 187 are formed on the bottom of substrate 140 as described above for bumps 114. Saw streets 188 are drawn to illustrate how pillars 130 are positioned within the saw streets in some embodiments.

A common issue with stacked packages is that reflowing solder bumps 186 for attachment of package 184 to interposer 120 also reflows bumps 125 between the interposer and substrate 140. Because stacked packages can have significant weight, especially in cases where multiple packages or chiplets are stacked onto each interposer 120, reflowing bumps 125 can cause collapse of interposer 120 toward 140. The collapse problem is present in all embodiments but is exacerbated in embodiments where packages 184 are mounted prior to molding with encapsulant 180. One problem caused by the collapse of bumps 125 is the possibility that components 126 may short circuit unintentionally to conductive layer 142, resulting in a bad unit.

FIG. 2n illustrates the tendency of gravity to collapse reflowed bumps 125 using arrows 190. Arrows 192 illustrate the expansion of SMA pillars 130 in the Austenite zone. The expansion of SMA pillars 130 provides extra support during reflow to counteract the collapse of bumps 125 under the weight of packages 184. A typical manufacturing process has a total of four reflows. Over the course of the four reflows, the height of bumps 125 is slowly reduced from the target value. SMA pillars 130 expand to reverse the collapse of bumps 125. The same anti-collapse benefit applies to each reflow step starting from the first reflow but becomes more important with each successive reflow. For smaller bumps 125, collapse can begin to cause significant defects at just the second reflow without correction with SMA pillars 130.

In FIG. 2o, the panel of packages is singulated through saw streets 188 using a saw blade or laser cutting tool 194. If SMA pillars 130 were disposed within saw street 188, the SMA pillars are removed by the singulation. FIG. 2p shows a completed semiconductor package 196 after singulation. Semiconductor package 196 has a package substrate 140 and interposer 120 with reduced warpage thanks to the use of SMA pillars 130 during manufacturing. The use of SMA pillars 130 also reduced the likelihood of solder bumps 125 collapsing and creating an unintentional short circuit. In some embodiments, SMA pillars 130 remain in the final package.

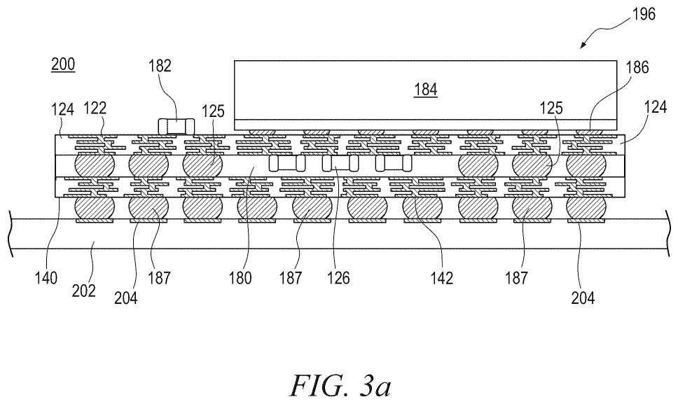

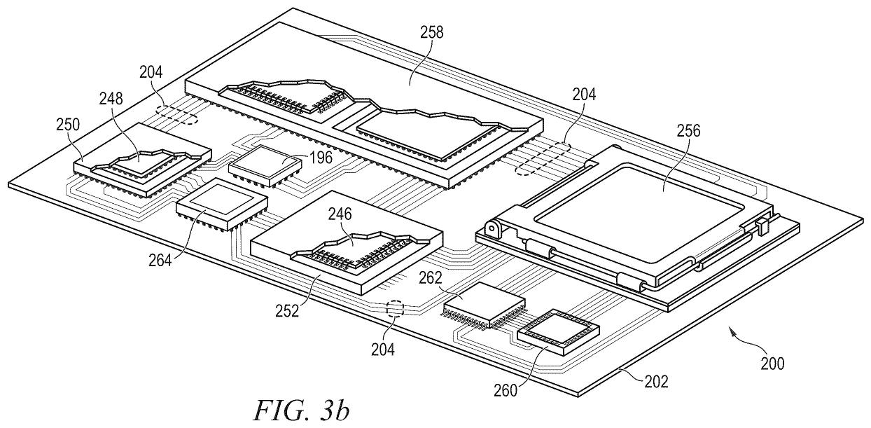

FIGS. 3a and 3b illustrate integrating the above-described semiconductor packages and devices, e.g., semiconductor package 196, into a larger electronic device 200. FIG. 3a illustrates a partial cross-section of semiconductor package 196 mounted onto a printed circuit board (PCB) or other substrate 202 as part of electronic device 200. Bumps 187 are reflowed onto conductive layer 204 of PCB 202 to physically attach and electrically connect semiconductor package 196 to the PCB. In other embodiments, thermocompression or other suitable attachment and connection methods are used. In some embodiments, an adhesive or underfill layer is used between semiconductor package 196 and PCB 202. The components of package 196, e.g., semiconductor die 104 and package 184, are electrically coupled to conductive layer 204 through bumps 187, substrate 140 bumps 125, and interposer 120.

FIG. 3b illustrates electronic device 200 having a chip carrier substrate or PCB 202 with a plurality of semiconductor packages disposed on a surface of PCB 202, including semiconductor package 196. Electronic device 200 can have one type of semiconductor package, or multiple types of semiconductor packages, depending on the application.

Electronic device 200 can be a stand-alone system that uses the semiconductor packages to perform one or more electrical functions. Alternatively, electronic device 200 can be a subcomponent of a larger system. For example, electronic device 200 can be part of a tablet, cellular phone, digital camera, communication system, or other electronic device. Alternatively, electronic device 200 can be a graphics card, network interface card, or other signal processing card that can be inserted into a computer. The semiconductor package can include microprocessors, memories, ASICS, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 202 may have a more irregular shape to fit conveniently into more ergonomic and smaller device shells.

In FIG. 3b, PCB 202 provides a general substrate for structural support and electrical interconnect of the semiconductor packages disposed on the PCB. Conductive signal traces 204 are formed over a surface or within layers of PCB 202 using evaporation, electrolytic plating, electroless plating, screen printing, or other suitable metal deposition process. Signal traces 204 provide for electrical communication between each of the semiconductor packages, mounted components, and other external system components. Traces 204 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 246 and flipchip 248, are shown on PCB 202. Additionally, several types of second level packaging, including ball grid array (BGA) 250, bump chip carrier (BCC) 252, land grid array (LGA) 256, multi-chip module (MCM) or SIP module 258, quad flat non-leaded package (QFN) 260, quad flat package 262, and embedded wafer level ball grid array (eWLB) 264 are shown disposed on PCB 202. In one embodiment, eWLB 264 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 202. In some embodiments, electronic device 200 includes a single attached semiconductor package, while other embodiments call for multiple interconnected packages. By combining one or more semiconductor packages over a single substrate, manufacturers can incorporate pre-made components into electronic devices and systems. Because semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing an interposer;
disposing a shape-metal alloy (SMA) structure over the interposer, wherein the SMA structure is formed of Nickel-Titanium;
disposing a solder bump over the interposer;
disposing an electrical component over the interposer;
disposing the interposer over a substrate with the SMA structure, solder bump, and electrical component between the interposer and substrate; and
reflowing the solder bump.

2. The method of claim 1, wherein reflowing the solder bump expands the SMA structure.

3. The method of claim 2, wherein the SMA structure shrinks while cooling after reflow.

4. The method of claim 1, further including disposing a semiconductor package over the interposer opposite the substrate.

5. The method of claim 4, further including reflowing the solder bump for a second time after disposing the semiconductor package over the interposer.

6. The method of claim 1, wherein a gap exists between the solder bump and substrate prior to reflow.

7. A method of making a semiconductor device, comprising:
providing an interposer;
disposing a shape-metal alloy (SMA) structure over the interposer;
disposing a solder bump over the interposer;
disposing the interposer over a substrate with the SMA structure and solder bump between the interposer and substrate; and
reflowing the solder bump.

8. The method of claim 7, wherein reflowing the solder bump expands the SMA structure.

9. The method of claim 8, wherein the SMA structure shrinks while cooling after reflow.

10. The method of claim 7, further including disposing a semiconductor package over the interposer opposite the substrate.

11. The method of claim 10, further including reflowing the solder bump for a second time after disposing the semiconductor package over the interposer.

12. The method of claim 7, wherein a gap exists between the solder bump and substrate prior to reflow.

13. The method of claim 7, further including singulating the substrate, wherein the singulation removes the SMA structure.

14. A method of making a semiconductor device, comprising:
providing an interposer;
disposing a shape-metal alloy (SMA) structure over the interposer; and
disposing the interposer over a substrate with the SMA structure between the interposer and substrate.

15. The method of claim 14, further including disposing a semiconductor package over the interposer opposite the substrate with a solder bump of the semiconductor package disposed between the semiconductor package and interposer.

16. The method of claim 15, further including reflowing the solder bump after disposing the semiconductor package over the interposer.

17. The method of claim 16, wherein reflowing the solder bump expands the SMA structure.

18. The method of claim 17, wherein the SMA structure shrinks while cooling after reflow.

19. The method of claim 14, further including disposing a plurality of SMA structures over the interposer with one of the plurality of SMA structures disposed at each corner of the interposer.

20. A semiconductor device, comprising:
an interposer;
a substrate; and
a shape-metal alloy (SMA) structure disposed between the interposer and substrate.

21. The semiconductor device of claim 20, further including a semiconductor package disposed over the interposer opposite the substrate.

22. The semiconductor device of claim 20, further including a solder bump disposed between the interposer and semiconductor package.

23. The semiconductor device of claim 20, further including an electrical component disposed between the interposer and substrate.

24. The semiconductor device of claim 20, further including a solder bump disposed between the interposer and substrate.

25. The semiconductor device of claim 20, further including a plurality of SMA structures disposed between the interposer and substrate, wherein one of the plurality of SMA structures is disposed at each corner of the interposer.
